(19) United States
(12) Patent Application Publication
(10) Pub. No.: US 2023/0411146 A1
(43) Pub. Date: Dec. 21, 2023

(54) SUBSTRATE PROCESSING METHOD AND SUBSTRATE PROCESSING DEVICE

(71) Applicant: Tokyo Electron Limited, Tokyo (JP)

(72) Inventors: Hiroki MURAKAMI, Nirasaki City, Yamanashi (JP); Masanobu IGETA, Tokyo (JP)

(21) Appl. No.: 18/035,401

(22) PCT Filed: Oct. 26, 2021
(86) PCT No.: PCT/JP2021/039550

§ 371 Date: May 4, 2023

(30) Foreign Application Priority Data
Nov. 6, 2020 (JP) 2020-186153

(51) Int. Cl. H01L 21/02; C23C 16/52; C23C 16/18

(52) U.S. Cl. CPC H01L 21/02274; H01L 21/02211; C23C 16/52; C23C 16/18

(57) ABSTRACT

A substrate processing method includes: a catalyst component supplying process of supplying a catalyst component, which is to be adsorbed on a substrate, to the substrate; a film-forming component supplying process of supplying a film-forming component, which forms an insulating film on the substrate in the presence of the catalyst component, to the substrate; and an inhibition component supplying process of supplying an inhibition component, which is to be adsorbed on the substrate and inhibits adsorption of the catalyst component on the substrate, to a front surface or a back surface of the substrate, wherein the inhibition component supplying process is performed before the catalyst component supplying process.

### TECHNICAL FIELD

The present disclosure relates to a substrate processing method and a substrate processing apparatus.

### BACKGROUND

Patent Document 1 discloses a substrate processing apparatus including: a reaction container in which substrates are processed; plate-shaped supports made of a conductive material and accommodating the substrates in recesses horizontally with upper surfaces thereof exposed; a support holder that holds the supports horizontally in multiple stages; and an induction heating device that heats the supports, which are held by the support holder, by induction heating in the reaction container.

### PRIOR ART DOCUMENT

### Patent Document

Patent Document 1: Japanese Patent Laid-open Publication No. 2010-153467

### SUMMARY

The present disclosure provides some embodiments of a substrate processing method capable of forming a film selectively on different surfaces of a substrate.

A substrate processing method according to an aspect of the present disclosure includes: a catalyst component supplying process of supplying a catalyst component, which is to be adsorbed on a substrate, to the substrate; a film-forming component supplying process of supplying a film-forming component, which forms an insulating film on the substrate in the presence of the catalyst component, to the substrate; and an inhibition component supplying process of supplying an inhibition component, which is to be adsorbed on the substrate and inhibits adsorption of the catalyst component on the substrate, to a front surface or a back surface of the substrate, wherein the inhibition component supplying process is performed before the catalyst component supplying process.

According to one embodiment of the present disclosure, it is possible to provide a substrate processing method capable of forming a film selectively on different surfaces of a substrate.

### BRIEF DESCRIPTION OF DRAWINGS

FIG. 1 is a flowchart of a substrate processing method according to an embodiment.

FIG. 2 is a schematic view of a substrate before being processed.

FIG. 3 is a schematic view of the substrate supplied with an inhibition component.

FIG. 4 is a schematic view of the substrate supplied with a catalyst component.

FIG. 5 is a schematic view of the substrate supplied with a film-forming component.

FIG. 6 is a schematic view of the substrate on which a film is formed.

FIG. 7 is a schematic view of the substrate in which the inhibition component has been removed from FIG. 6.

FIG. 8 is a view showing a state in which the catalyst component is adsorbed on the substrate.

FIG. 9 is a view showing a state in which the film-forming component is supplied to the substrate.

FIG. 10 is a view showing a state in which the film-forming component is further supplied from FIG. 9.

FIG. 11 is a view showing a state in which the film is formed on the substrate.

FIG. 12 is a view showing a state in which the inhibition component is adsorbed on the substrate.

FIG. 13 is a view showing a state in which the catalyst component is supplied from FIG. 12.

FIG. 14 is a view showing a state in which the film-forming component is supplied from FIG. 13.

FIG. 15 is a schematic view showing a part of a substrate processing apparatus according to an embodiment.

FIG. 16 is a schematic view showing a part of a substrate processing apparatus according to an embodiment.

### DETAILED DESCRIPTION

Embodiments of the present disclosure will now be described with reference to the drawings. It should be noted that portions common in each drawing are denoted by the same or corresponding reference numerals, and explanation thereof may be omitted.

### <Substrate Processing Method>

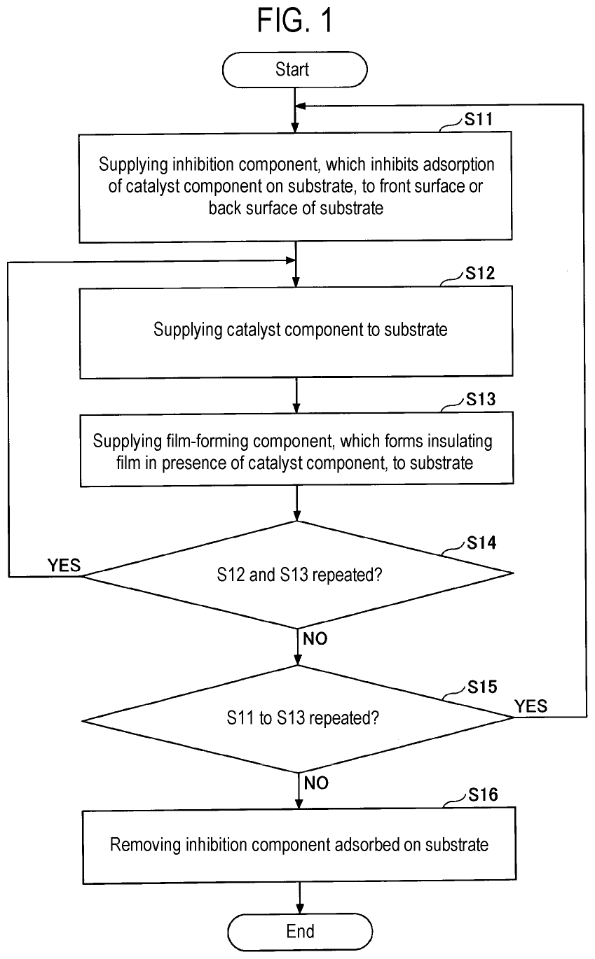

FIG. 1 is a flowchart of a substrate processing method according to an embodiment.

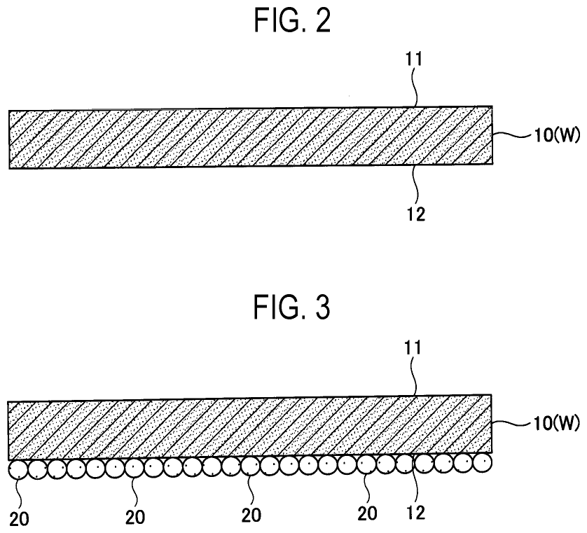

FIGS. 2 to 7 show processes performed on a substrate in the substrate processing method according to the embodiment.

The substrate processing method of the present embodiment includes: a catalyst component supplying process of supplying a catalyst component, which is to be adsorbed on a substrate, to the substrate; a film-forming component supplying process of supplying a film-forming component, which forms an insulating film on the substrate in the presence of the catalyst component, to the substrate; and an inhibition component supplying process of supplying an inhibition component, which is to be adsorbed on the substrate and inhibits adsorption of the catalyst component on the substrate, to a front surface or back surface of the substrate, wherein the inhibition component supplying process is performed before the catalyst component supplying process.

In the substrate processing method of the present embodiment, as shown in FIG. 1, steps S11 to S16 are executed to process the substrate (see FIGS. 2 to 7).

In step S11, an inhibition component 20 is supplied to a front surface 11 or a back surface 12 of a substrate 10 (see FIG. 1). The inhibition component 20 is adsorbed on the substrate 10. In the present embodiment, the inhibition component 20 is supplied only to the back surface 12 of the substrate 10, so that the inhibition component 20 is adsorbed on the back surface 12 of the substrate 10 (see FIGS. 2 and 3). Note that step S11 is an example of the inhibition component supplying process in the substrate processing method of the present embodiment.

The substrate 10 is composed of a semiconductor wafer such as silicon (Si) wafer (hereinafter referred to as a silicon wafer W or a wafer W), and elements and wiring patterns are formed on the front surface 11 or the back surface 12 of the substrate 10. The substrate 10 (the wafer W) is not limited to such a wafer, and may be a glass substrate for manufacturing a flat panel display. The substrate 10 is an example of the substrate processed by the substrate processing method of the present disclosure.

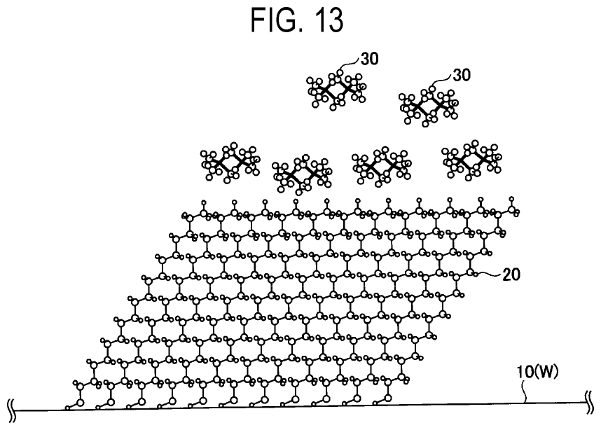

The inhibition component 20 is not particularly limited. Examples of the inhibition component 20 may include an organic film or an organic fluoride compound, a self-assembled monolayer (hereinafter referred to as an SAM or an SAM film), and the like. Here, the self-assembled monolayer refers to a monomolecular film in which single molecules spontaneously aggregate due to intermolecular interaction and are oriented uniformly. In the present embodiment, as shown in FIG. 12, the inhibition component 20 is adsorbed on the substrate 10 to form an SAM film.

In addition, when such an SAM film is formed on the substrate 10, an organic sulfur compound, an organic silane-based compound, or the like can be used as the inhibition component 20.

Examples of the organic sulfur compound that forms the SAM film may include: alkylthiols such as 1-octadecanethiol (SH—C₁₈H₃₇) and 2-(heptadecafluorooctyl)ethanethiol (SH—C₁₀H₄F₁₇); arylthiols such as thiophenol, thiophenol derivatives, tolylthiol, and tolylthiol derivatives; and the like.

Examples of the organic silane compound that forms the SAM film may include: aminosilane compounds such as 3-aminopropyltrimethoxysilane, 3-aminopropyltriethoxysilane, 3-(2-aminoethyl)aminopropyltrimethoxysilane, and 3-(2-aminoethyl)aminopropylmethyldimethoxysilane; alkylsilane compounds such as trihalogenalkylsilane and trialkoxyalkylsilanes; and the like.

In addition, the inhibition component 20 adsorbed on the substrate 10 inhibits adsorption of a catalyst component 30 on the substrate 10.

The catalyst component 30 is adsorbed on the substrate 10, but the adsorption of the catalyst component 30 on the substrate 10 is easily inhibited by the presence of the inhibition component 20. The catalyst component 30 is not particularly limited. For example, a metal compound can be used as the catalyst component 30.

Specific examples of the metal compound may include alkyl aluminum such as trimethylaluminum (hereinafter referred to as TMA) and aluminum compounds such as aluminum chloride (AlCl₃).

In addition, metal compounds other than aluminum compound may include trimethylgallium (hereinafter referred to as TMG), tetrakisethylmethylaminohafnium (TEMAH), hafnium chloride (HfCl₄), tetrakisdimethylaminotitanium (TDMAT), titanium chloride (TiCl₄), and the like.

Among the metal compounds described above, trimethylaluminum (TMA) and trimethylgallium (TMG), which are raw materials that are easily inhibited, may be used.

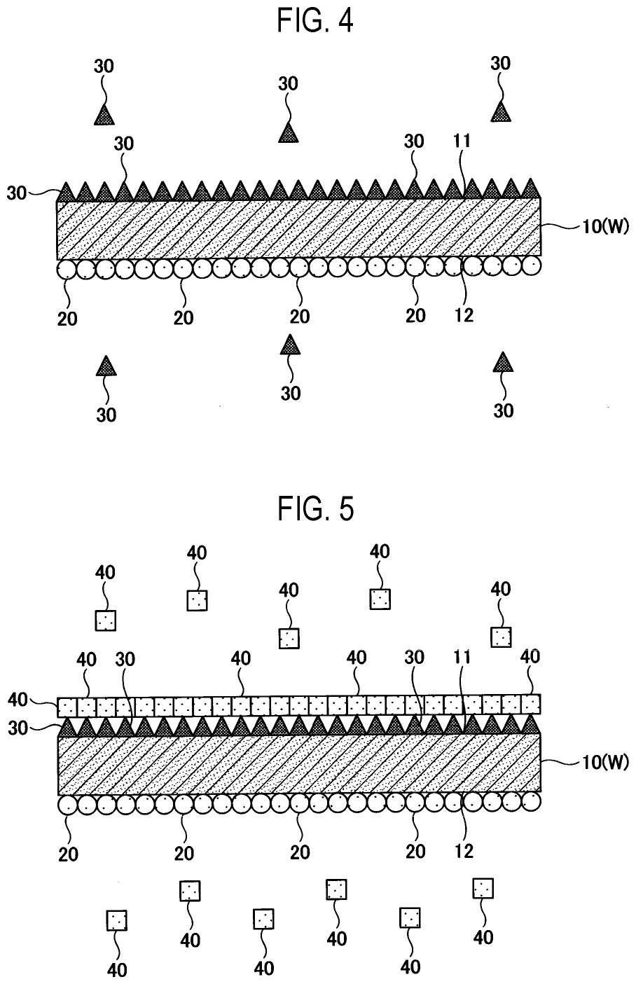

In step S12, the catalyst component 30 is supplied to the substrate 10. Specifically, after step S11, the catalyst component 30 is adsorbed on the substrate 10 on which the film (SAM or SAM film) of the inhibition component 20 has been formed (see FIG. 4). Step S12 is an example of the catalyst component supplying process in the substrate processing method of the present embodiment. In the present embodiment, step S11 is performed before step S12, and the inhibition component supplying process is performed before the catalyst component supplying process.

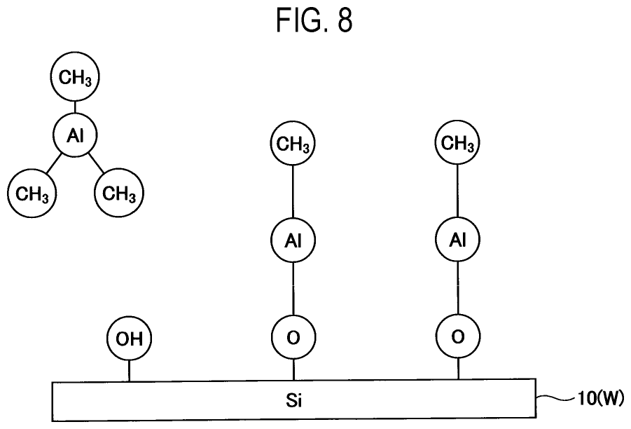

FIG. 8 shows a state in which the catalyst component 30 is adsorbed on the substrate 10. In step S12, when the substrate 10 is a silicon wafer and the catalyst component 30 is a metal compound (for example, TMA), TMA is adsorbed on an interface of silicon (OH group) as shown in FIG. 8.

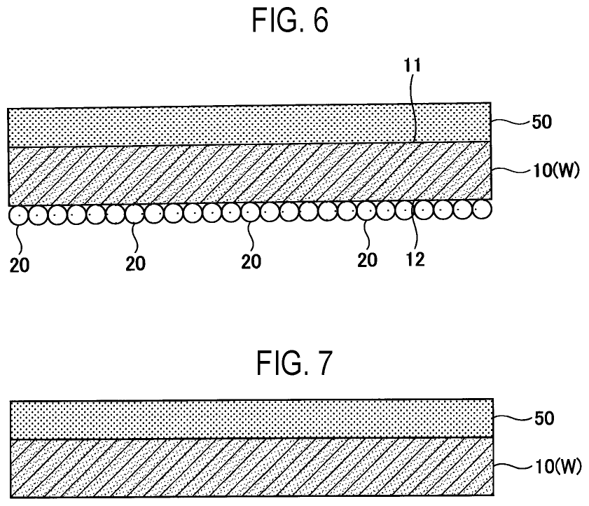

In step S13, a film-forming component 40 is supplied to the substrate 10. The film-forming component 40 forms an insulating film 50 on the substrate 10 in the presence of the catalyst component 30. Specifically, in a state in which the inhibition component 20 is adsorbed on the back surface 12 of the substrate 10 and the catalyst component 30 is adsorbed on the front surface 11 of the substrate 10 after step S12, when the film-forming component 40 is supplied to the substrate 10 (see FIG. 5), the insulating film 50 is formed only on the front surface 11 of the substrate 10 (see FIG. 6).

Here, the insulating film 50 is a target film to be formed on the substrate 10. Step S13 is an example of the film-forming component supplying process in the substrate processing method of the present embodiment.

The film-forming component 40 is not particularly limited. For example, an organic silane compound can be used as the film-forming component 40.

Specific examples of the organic silane compound may include silanol compounds such as tris(tert-pentoxy)silanol (hereinafter referred to as TPSOL) and tris(tert-butoxy)silanol (hereinafter referred to as TBSOL), silanol raw materials, silicon alkoxides, metal alkoxide compounds, raw materials containing Si—N bonds such as aminosilanes, materials containing metal amides, and the like.

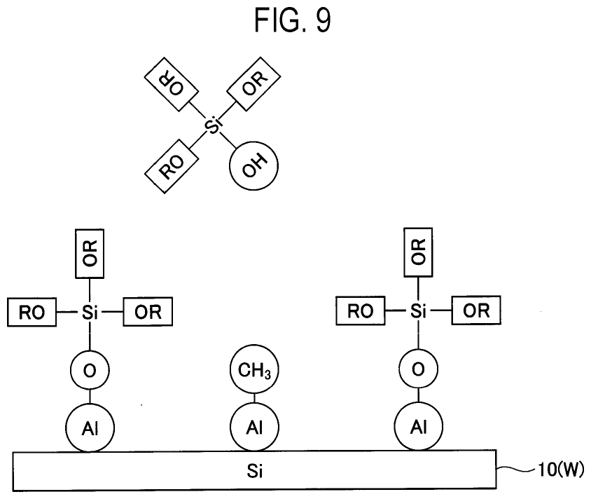

FIG. 9 shows a state in which the film-forming component 40 has been supplied to the substrate 10. In step S13, when the substrate 10 is silicon (Si) and the film-forming component 40 is TPSOL (Si(OR)₃OH, where R is an alkyl group having 1 or more carbon atoms), as shown in FIG. 9, TPSOL is adsorbed on silicon in the presence of TMA.

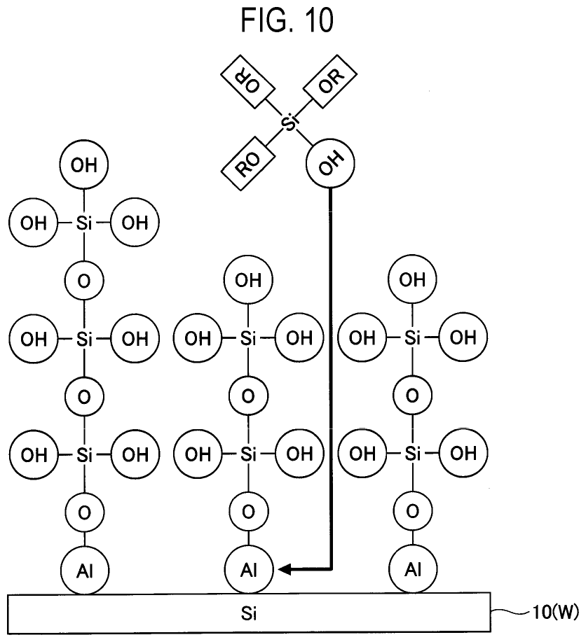

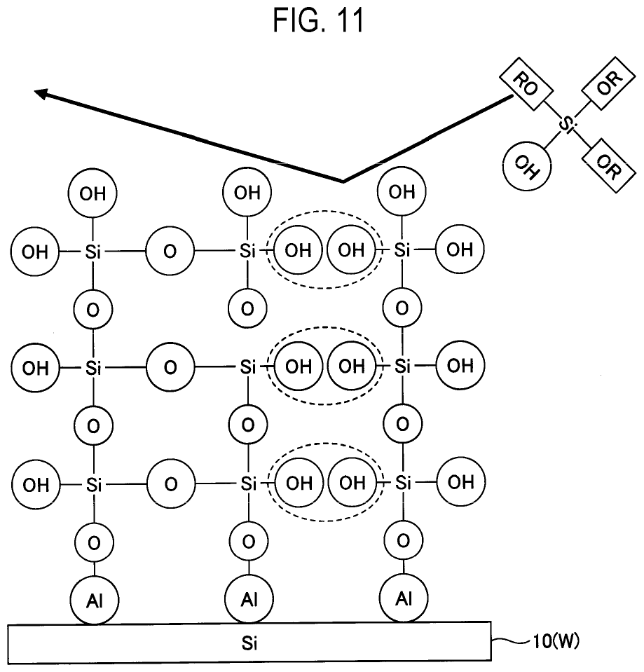

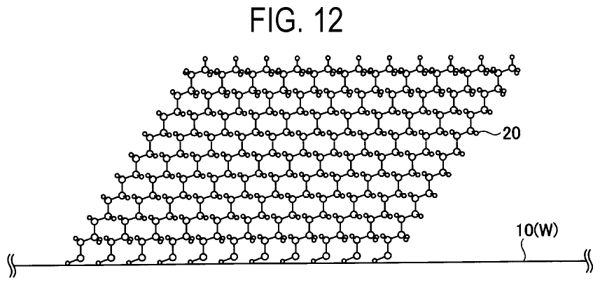

In step S14, the catalyst component supplying process and the film-forming component supplying process are repeated as necessary. Specifically, steps S12 and S13 are repeated. Thus, TMA is further adsorbed on the interface of silicon (OH group), and TPSOL is further supplied and deposited on silicon in the presence of TMA (see FIG. 10). Thereafter, in the presence of TMA, TPSOL is further supplied to form a silicon oxide film as the insulating film 50 on silicon (see FIG. 11).

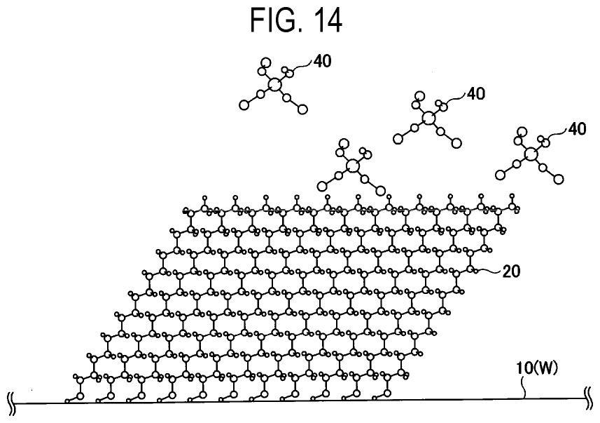

On the other hand, as shown in FIGS. 12 and 13, even when TMA is supplied as the catalyst component 30 to the substrate 10 on which the SAM film 20 has been formed, adsorption of TMA on the substrate 10 (silicon) is inhibited, so that TMA is not adsorbed on the substrate 10 (silicon). In addition, as shown in FIG. 14, even when TPSOL is supplied as the film-forming component 40 to the substrate 10 on which TMA is not adsorbed, an insulating film such as a silicon oxide film is not formed on the substrate 10.

In step S15, the inhibition component supplying process, the catalyst component supplying process, and the film-forming component supplying process may be repeated as necessary. Specifically, steps S11 to S15 are repeated after step S15. Thus, the SAM film 20 is further formed on the substrate 10 on which the inhibition component (SAM) 20 has been adsorbed in step S11 (see FIGS. 12 to 14).

In step S16, the inhibition component 20 adsorbed on the substrate 10 is removed (see FIGS. 1 and 7). Step S16 is an example of a removing process in the substrate processing method of the present embodiment. The removing process is performed after the film-forming component supplying process. Specifically, step S16 is executed after step S13.

In step S16, plasma of an oxygen-containing gas is supplied to the substrate 10. Here, the oxygen-containing gas is not particularly limited. Examples of the oxygen-containing gas may include oxygen, ozone, and the like. Plasma refers to a state in which molecules are ionized into positively charged particles (ions) and negatively charged electrons. In the present embodiment, as the plasma of the oxygen-containing gas is supplied to the substrate 10, the inhibition component 20 adsorbed on the back surface of the substrate 10 is removed (see FIGS. 6 and 7).

In addition, the inhibition component removing process can be performed not only with oxygen but also with a reducing gas. For example, H₂, NH₃, plasmarized H₂ or NH₃, or a hydrazine-containing gas can be used. Since a main skeleton of the inhibition component is a straight-chain structure such as alkyl, it can be etched in a state of COx by oxidation. Further, since the inhibition component has an organic structure, it can be easily removed by hydrogen or ammonia radicals.

In the substrate processing method of the present embodiment, as described above, by performing the inhibition component supplying process before the catalyst component supplying process, adsorption of the catalyst component 30 on the substrate 10 is inhibited and the catalyst component 30 is not adsorbed on the front surface 11 or the back surface 12 of the substrate 10 to which the inhibition component 20 is supplied (see FIG. 4).

As a result, even when the film-forming component 40 is supplied to the substrate 10 on which the catalyst component 30 is not adsorbed, an insulating film such as a silicon oxide film is not formed on the substrate 10 (see FIGS. 5 and 6). Therefore, according to the present embodiment, it is possible to form a film selectively on different surfaces of the substrate 10.

In addition, in the present embodiment, as described above, in the inhibition component supplying process (step S11), the inhibition component 20 is supplied only to the back surface 12 of the substrate 10. Thus, the catalyst component 30 is adsorbed on the front surface 11 of the substrate 10, but is not adsorbed on the back surface 12 of the substrate 10. In such a state, when the film-forming component 40 is supplied to the substrate 10 in the film-forming component supplying process (step S13), the insulating film 50 is formed on the front surface 11 of the substrate 10 and is not formed on the back surface 12 of the substrate 10. Therefore, according to the present embodiment, the insulating film 50 can be formed selectively on the front surface 11 of the substrate 10.

In the present embodiment, as described above, by using an organic silane compound as the film-forming component 40, the insulating film 50 can be formed stably on the substrate 10 by a catalytic effect. In addition, by using TPSOL or TBSOL as the organic silane compound, the insulating film 50 can be formed to have high adhesion to the substrate 10.

In the present embodiment, as described above, by using a metal compound as the catalyst component 30, a film-forming reaction of the film-forming component 40 can be promoted. In addition, by using trimethylaluminum (TMA) or trimethylgallium (TMG) as the metal compound, adhesion of the insulating film 50, which is formed by the film-forming component 40, to the substrate 10 can be enhanced.

In the present embodiment, as described above, by repeating the catalyst component supplying process (step S12) and the film-forming component supplying process (step S13), a film thickness or film quality of the insulating film 50 formed on the substrate 10 can be adjusted while forming the film selectively on different surfaces of the substrate 10.

In the present embodiment, as described above, by using an organic sulfur compound or an organic silane-based compound, which forms a self-assembled monolayer (SAM film) on the substrate 10, as the inhibition component 20, adsorption of the catalyst component 30 on the substrate 10 can be inhibited even when the catalyst component 30 is supplied to the substrate 10 on which the SAM film 20 is formed.

As a result, since the catalyst component 30 is not adsorbed on the substrate 10 on which the SAM film 20 is formed, no insulating film is formed thereon even when the film-forming component 40 is supplied. Therefore, according to the present embodiment, selective film formation on different surfaces of the substrate 10 can be achieved.

In addition, by using an organic sulfur compound, which forms an SAM film on the substrate 10, as the inhibition component 20, a stable self-assembled monolayer can be formed on the substrate 10. Therefore, adsorption of the catalyst component 30 on the substrate 10 can be effectively inhibited, and selective film formation on different surfaces of the substrate 10 can be achieved with high accuracy.

In addition, by using an organic silane-based compound, which forms an SAM film on the substrate 10, as the inhibition component 20, adsorption of the catalyst component 30 on the substrate 10 can be effectively inhibited, and selective film formation on different surfaces of the substrate 10 can be achieved with high accuracy.

In the present embodiment, as described above, by repeating the inhibition component supplying process (step S11), the catalyst component supplying process (step S12), and the film-forming component supplying process (step S13), selective film formation on different surfaces of the substrate 10 can be performed while maintaining a thickness of a film of the inhibition component 20 formed on the substrate 10. In addition, even when the film of the inhibition component 20 deteriorates, the substrate 10 can be reinforced by the inhibition component 20 to maintain an inhibition force.

In the present embodiment, as described above, the inhibition component 20 adsorbed on the substrate 10 can be removed from the substrate 10 by the removing process (step S16) of removing the inhibition component 20 adsorbed on the substrate 10. In addition, by performing the removing process (step S16) after the film-forming component supplying process (step S13), the inhibition component 20, which has become unnecessary after the insulating film 50 is formed on the substrate 10, can be selectively removed from the substrate 10.

In the present embodiment, as described above, by supplying plasma of an oxygen-containing gas to the substrate 10 in the removing process (step S16), even when an adsorption force of the inhibition component 20 to the substrate 10 is strong, the inhibition component 20 which has become unnecessary can be removed from the substrate 10. In addition, even when the film of the inhibition component 20 adsorbed on the substrate 10 is thick, the inhibition component 20 which has become unnecessary can be selectively removed from the substrate 10.

In addition, in the present embodiment, as described above, by supplying H₂, NH₃, plasmarized H₂ or NH₃, or a hydrazine-containing gas to the substrate 10 in the removing process (step S16), the inhibition component having an organic structure can be removed by the hydrogen or ammonia radicals.

### <Substrate Processing Apparatus>

A substrate processing apparatus according to the present embodiment is a substrate processing apparatus having a controller that controls processing of a substrate, wherein the controller performs a control to: supply a catalyst component, which is to be adsorbed on the substrate, to the substrate; supply a film-forming component, which forms an insulating film on the substrate in the presence of the catalyst component, to the substrate; supply an inhibition component, which is to be adsorbed on the substrate and inhibits adsorption of the catalyst component on the substrate, to the substrate; and supply the inhibition component to a front surface or a back surface of the substrate before the catalyst component is supplied to the substrate.

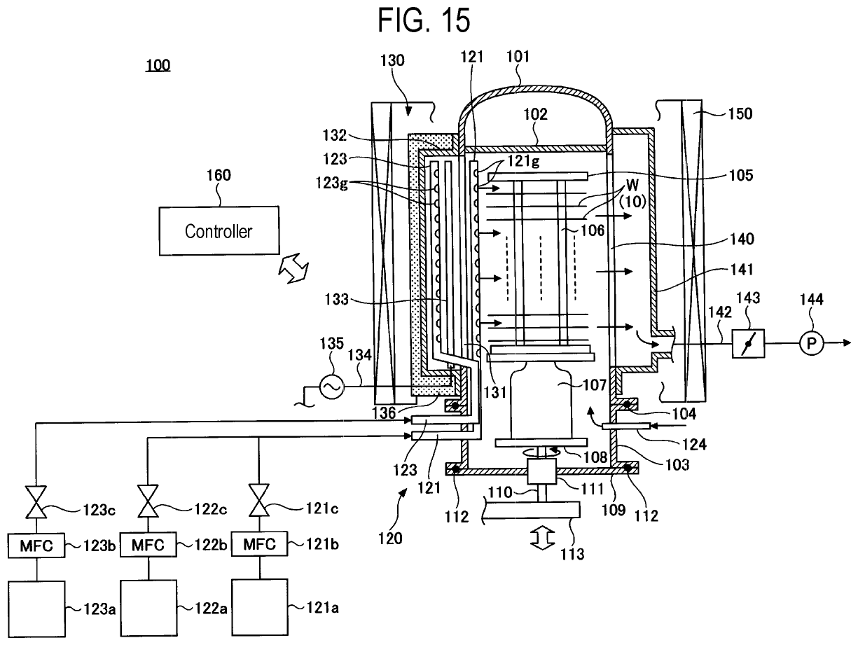

FIG. 15 is a schematic view showing a part of a substrate processing apparatus (substrate processing apparatus 100) according to an embodiment. The substrate processing apparatus 100 performs forming a target film (insulating film) by using, for example, a substrate having an inhibition component formed on a back surface of the substrate, and removing the inhibition component. In addition, an apparatus that forms the inhibition component on the back surface of the substrate will be described later.

The substrate processing apparatus 100 has a cylindrical process container 101 with an open lower end and a ceiling. The entire process container 101 is made of, for example, quartz. A ceiling plate 102 made of quartz is provided in a vicinity of an upper end of the process container 101, and a region below the ceiling plate 102 is sealed. A cylindrical manifold 103 made of metal is connected to the opening at the lower end of the process container 101 via a seal 104 such as an O-ring.

The manifold 103 supports the lower end of the process container 101, and a wafer boat 105, in which a plurality of (for example, 25 to 150 sheets) semiconductor wafers (hereinafter referred to as “substrates W”) is mounted in multiple stages (the substrate W corresponds to the substrate 10 described above), is inserted into the process container 101 from below the manifold 103. As described above, the substrates W are accommodated substantially horizontally in the process container 101 at intervals along a vertical direction.

The wafer boat 105 is made of, for example, quartz. The wafer boat 105 has three rods 106 (two rods are shown in FIG. 15), and the substrates W are supported by grooves (not shown) formed in the rods 106.

The wafer boat 105 is placed on a table 108 via a heat insulating tube 107 made of quartz. The table 108 is supported on a rotary shaft 110 penetrating through a lid 109, which is made of metal (stainless steel) and opens and closes the lower end opening of the manifold 103.

A magnetic fluid seal 111 is provided in a penetrating portion of the rotary shaft 110 to hermetically seal and rotatably support the rotary shaft 110. A seal 112 is provided between a peripheral portion of the lid 109 and the lower end of the manifold 103 to keep an interior of the process container 101 airtight.

The rotary shaft 110 is attached to a leading end of an arm 113 supported by an elevating mechanism (not shown) such as a boat elevator. The wafer boat 105 and the lid 109 are moved vertically as a unit to be inserted into and removed from the process container 101. In addition, the table 108 may be fixed to a side of the lid 109, and the substrates W may be processed without rotating the wafer boat 105.

The substrate processing apparatus 100 also has a gas supply 120 that supplies predetermined gases such as a processing gas and a purge gas into the process container 101.

The gas supply 120 has gas supply pipes 121, 123, and 124.

The gas supply pipe 121 is made of, for example, quartz. The gas supply pipe 121 penetrates inward through a sidewall of the manifold 103, is bent upward, and extends vertically. In a vertical portion of the gas supply pipe 121, a plurality of gas holes 121g is formed at predetermined intervals over a vertical length corresponding to a wafer support range of the wafer boat 105. Each gas hole 121g discharges a gas horizontally.

The gas supply pipe 123 is made of, for example, quartz. The gas supply pipe 123 penetrates inward through the sidewall of the manifold 103, is bent upward, and extends vertically. In a vertical portion of the gas supply pipe 123, a plurality of gas holes 123g is formed at predetermined intervals over a vertical length corresponding to the wafer support range of the wafer boat 105. Each gas hole 123g discharges a gas horizontally.

The gas supply pipe 124 is made of, for example, quartz and is composed of a short quartz pipe extending through the sidewall of the manifold 103.

The vertical portion of the gas supply pipe 121 (the vertical portion where the gas holes 121g are formed) is provided in the process container 101. A processing gases are supplied to the gas supply pipe 121 from gas sources 121a and 122a via gas pipes. Flow rate controllers 121b and 122b and opening/closing valves 121c and 122c are provided in the gas pipes. Thus, the processing gases from the gas sources 121a and 122a are supplied into the process container 101 via the gas pipes and the gas supply pipe 121.

In the present disclosure, as the processing gas from the gas source 121a, a gas containing the catalyst component 30 (for example, a metal compound such as TMA) is supplied from the gas supply pipe 121 into the process container 101. As a result, step S12 described above is executed, so that the catalyst component is supplied to the substrate W on which an SAM film, which will be described later, is formed (see FIGS. 1, 4, 8, and 15).

In addition, in the present disclosure, as the processing gas from the gas source 122a, a gas containing the film-forming component 40 (for example, an organic silane compound such as TPSOL) is supplied from the gas supply pipe 121 into the process container 101. As a result, step S13 described above is executed, so that the film-forming component is further supplied to the substrate W, on which the SAM film, which will be described later, has been formed and the catalyst component has been supplied (see FIGS. 1, 5, 6, 9 to 11, and 15).

The vertical portion of the gas supply pipe 123 (the vertical portion where the gas holes 123g are formed) is provided in a plasma generation space to be described later. A processing gas is supplied to the gas supply pipe 123 from a gas source 123a via a gas pipe. A flow rate controller 123b and an opening/closing valve 123c are provided in the gas pipe. Thus, the processing gas from the gas source 123a is supplied to the plasma generation space via the gas pipe and the gas supply pipe 123, is plasmarized in the plasma generation space, and is supplied into the process container 101.

In the present disclosure, as the processing gas from the gas source 123a, an oxygen-containing gas (for example, ozone gas) is supplied from the gas supply pipe 123 to the plasma generation space, is plasmarized in the plasma generation space, and is supplied into the process container 101. As a result, step S16 described above is executed, so that plasma of the oxygen-containing gas is supplied to the substrate 10 (see FIGS. 1, 6, 7, and 15).

A purge gas is supplied to the gas supply pipe 124 from a purge gas source (not shown) via a gas pipe. A flow rate controller (not shown) and an opening/closing valve (not shown) are provided in the gas pipe (not shown). Thus, the purge gas from the purge gas source is supplied into the process container 101 via the gas pipe and the gas supply pipe 124.

An inert gas such as argon (Ar) or nitrogen (N₂) can be used as the purge gas. Although a case where the purge gas is supplied from the purge gas source into the process container 101 via the gas pipe and the gas supply pipe 124 has been described, without being limited to this, the purge gas may be supplied from the gas supply pipe 121.

A plasma generation mechanism 130 is formed on a sidewall of the process container 101. The plasma generation mechanism 130 plasmarizes the processing gas from the gas source 123a.

The plasma generation mechanism 130 includes a plasma partition wall 132, a pair of plasma electrodes 133 (one electrode is shown in FIG. 15), a power supply line 134, a radio-frequency power supply 135, and an insulation protection cover 136.

The plasma partition wall 132 is hermetically welded to an outer wall of the process container 101. The plasma partition wall 132 is made of, for example, quartz. The plasma partition wall 132 has a concave cross section and covers an opening 131 formed in the sidewall of the process container 101. The opening 131 is formed to be elongated in the vertical direction so as to cover all the substrates W supported by the wafer boat 105 in the vertical direction.

The gas supply pipe 123 for discharging the processing gas is disposed in an inner space, which is defined by the plasma partition wall 132 and in communication with the interior of the process container 101, that is, in the plasma generation space. In addition, the gas supply pipe 123 for discharging the processing gas is provided at a location close to the substrates W along an inner wall of the process container 101 outside the plasma generation space.

The pair of plasma electrodes 133 (one electrode is shown in FIG. 15), each of which has an elongated shape, are disposed on outer surfaces of walls on both sides of the plasma partition wall 132 to face with each other along the vertical direction. Each plasma electrode 133 is held by, for example, a holder (not shown) provided on a side surface of the plasma partition wall 132. The power supply line 134 is connected to a lower end of each plasma electrode 133.

The power supply line 134 electrically connects each plasma electrode 133 and the radio-frequency power supply 135. In the example shown in FIG. 15, the power supply line 134 has one end connected to the lower end of each plasma electrode 133 and the other end connected to the radio-frequency power supply 135.

The radio-frequency power supply 135 is connected to the lower end of each plasma electrode 133 via the power supply line 134, and supplies radio-frequency power (RF power) of, for example, 13.56 MHz to the pair of plasma electrodes 133. Thus, the radio-frequency power is applied into the plasma generation space defined by the plasma partition wall 132.

The processing gas discharged from the gas supply pipe 123 is plasmarized in the plasma generation space into which the radio-frequency power is applied, and is supplied into the process container 101 via the opening 131.

The insulation protection cover 136 is attached to the outside of the plasma partition wall 132 so as to cover the plasma partition wall 132. A coolant passage (not shown) is provided inside the insulation protection cover 136, and the plasma electrodes 133 are cooled by flowing a coolant such as cooled nitrogen (N₂) gas via the coolant passage.

In addition, a shield (not shown) may be provided between the plasma electrodes 133 and the insulation protection cover 136 so as to cover the plasma electrodes 133. The shield is made of, for example, a good conductor such as metal, and is grounded.

An exhaust port 140 for vacuum-exhausting the interior of the process container 101 is provided in a portion of the sidewall of the process container 101 facing the opening 131. The exhaust port 140 is formed correspondingly to the wafer boat 105 and is elongated vertically. An exhaust port cover 141 formed with a U-shaped cross section is attached to a portion of the process container 101 corresponding to the exhaust port 140 so as to cover the exhaust port 140. The exhaust port cover 141 extends upward along the sidewall of the process container 101.

An exhaust pipe 142 for exhausting the process container 101 via the exhaust port 140 is connected to a lower portion of the exhaust port cover 141. An exhaust device 144, which includes a pressure control valve 143 for controlling an internal pressure of the process container 101 and a vacuum pump, is connected to the exhaust pipe 142. The interior of the process container 101 is vacuum-exhausted by the exhaust device 144 via the exhaust pipe 142.

In addition, a cylindrical heating mechanism 150 for heating the process container 101 and the substrates W therein is provided so as to surround an outer periphery of the process container 101.

In addition, the substrate processing apparatus 100 has a controller 160. In the substrate processing apparatus 100, substrate processing is controlled under the control of the controller 160.

For example, the controller 160 performs controlling operations of respective components of the substrate processing apparatus 100, controlling a supply and stop of each gas by opening and closing the opening/closing valves 121c to 123c, controlling gas flow rates by the flow rate controllers 121b to 123b, and controlling the exhaust by the exhaust device 144. In addition, the controller 160 performs, for example, an on/off control of the radio-frequency power by the radio-frequency power supply 135 and a temperature control of the substrates W by the heating mechanism 150.

The controller 160 may be, for example, a computer or the like. In addition, a computer program for operating respective components of the substrate processing apparatus 100 is stored in a storage medium. The storage medium may be, for example, a flexible disk, a compact disc, a hard disk, a flash memory, a DVD, or the like.

In the present disclosure, the substrate processing is controlled by the controller 160, and steps S12 to S16 described above are executed, so that the catalyst component 30 to be adsorbed on the substrate 10 (W) is supplied into a chamber 210 of a substrate processing apparatus 200, which will be described later, and the film-forming component 40 that forms the insulating film 50 on the substrate 10 (W) in the presence of the catalyst component 30 is supplied into the chamber 210 (see FIGS. 4 to 7, 9 to 11, and 15).

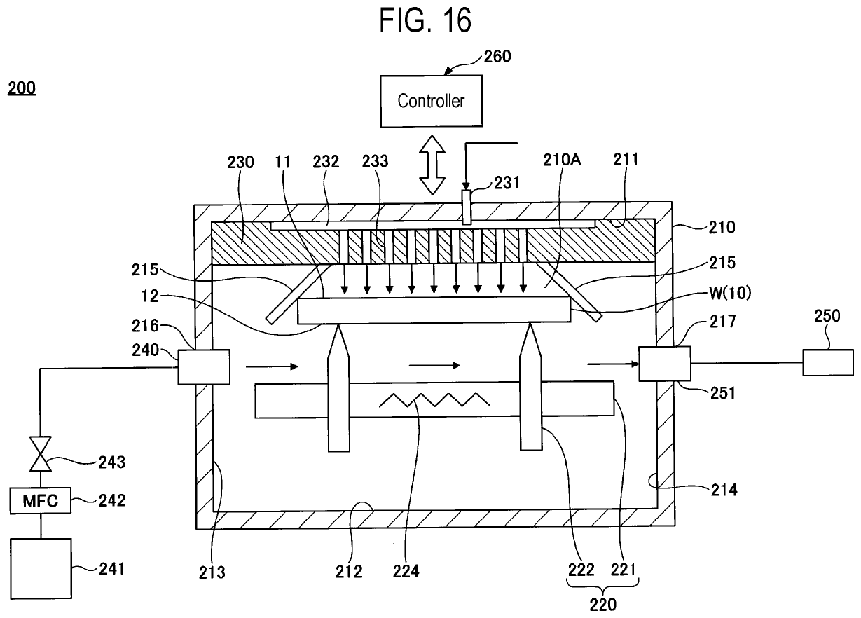

FIG. 16 is a schematic view showing a part of a substrate processing apparatus (substrate processing apparatus 200) according to an embodiment. The substrate processing apparatus 200 is an apparatus that supplies the inhibition component to, for example, the back surface of a substrate before the catalyst component is supplied to the substrate in the above-described substrate processing apparatus 100.

The substrate processing apparatus 200 includes the chamber 210, a stage 220, a shower head 230, a gas supply 240, an exhaust system 250, and a controller 260. In the substrate processing apparatus 200, step S11 is executed to form the inhibition component 20 on the substrate 10 (W) (see FIGS. 1 to 3). The substrate processing apparatus 200 is an example of the substrate processing apparatus according to the present embodiment.

The chamber 210 is surrounded by a ceiling surface 211, a bottom surface 212, and sidewalls 213 and 214. An interior of the chamber 210 is configured as a cylindrical airtight vacuum container and a vacuum atmosphere is formed therein. A shape of the vacuum container that constitutes the chamber 210 is not limited to such a cylindrical shape, and the interior thereof may have another shape such as a rectangular parallelepiped.

A heater (not shown) may be provided in the ceiling surface 211 and the sidewalls 213 and 214 of the chamber 210. By providing such a heater, an internal temperature of the chamber 210 can be adjusted.

The stage 220 is provided on a side of a lower portion (a side of the bottom surface 212) inside the chamber 210. The stage 220 includes a mounting table 221 and the substrate 10 (silicon wafer W) is mounted on the stage 220. The mounting table 221 of the stage 220 is formed to be circular in a plan view, and the substrate 10 (W) is mounted on a horizontally formed surface (an upper surface) of the mounting table 221. A shape of the mounting table 221 of the stage 220 is not limited to such a circular shape, and may be another shape such as a quadrangle in a plan view.

A heater 224 may be provided in the mounting table 221 of the stage 220. By providing the heater 224, a temperature of the substrate 10 (W) can be adjusted. In addition, a temperature of a processing gas supplied into the chamber 210 can be adjusted by the heater 224.

The stage 220 is supported inside the chamber 210 by a support pillar (not shown) provided on the side of the bottom surface 212 of the chamber 210. For example, three lift pins 222 (only two are shown) that move vertically are provided outside the support pillar in a circumferential direction. The lift pins 222 are respectively inserted into through-holes provided in the stage 220 at intervals in the circumferential direction.

The lift pins 222 are controlled by an elevating mechanism (not shown) and are driven to move vertically by a driving mechanism (not shown).

Specifically, when a transfer mechanism (not shown) that supports the substrate 10 (W) is loaded into the chamber 210, the lift pins 222 protrude from the surface of the stage 220 to support the substrate 10 (W) inside the chamber 210, whereby the substrate 10 (W) is raised. The raised substrate 10 (W) approaches a wing 215, which will be described later, to form a space 210A surrounded by the ceiling surface 211 of the chamber 210, the front surface 11 of the substrate 10, and the wing 215.

The shower head 230 is provided on a side of an upper portion (a side of the ceiling surface 211) inside the chamber 210. The shower head 230 has a gas supply 231, a gas diffusion chamber 232, and a plurality of gas discharge ports 233. A purge gas is supplied to the gas supply 231 from a purge gas source (not shown) via a gas pipe. A flow rate controller (not shown) and an opening/closing valve (not shown) are provided in the gas pipe (not shown).

The gas supply 231 is in communication with the gas diffusion chamber 232. The plurality of gas discharge ports 233 is in communication with the gas diffusion chamber 232 and the chamber 210. In the present disclosure, the shower head 230 is configured to supply the purge gas from the gas supply 231 into the chamber 210 via the gas diffusion chamber 232 and the plurality of gas discharge ports 233.

An inert gas such as argon (Ar) or nitrogen (N₂) can be used as the purge gas supplied from the gas supply 231.

The wing 215 having an annular shape widening toward the bottom surface 212 of the chamber 210 is provided below the shower head 230. The wing 215 comes close to the substrate 10 (W) by raising the lift pins 222 to form the space 210A between the front surface 11 of the substrate 10 (W) and a lower surface of the shower head 230.

The shape of the wing 215 is not particularly limited, and may be changed according to a shape of the substrate 10 (W). In addition, in the present embodiment, the wing 215 is fixed to a lower side of the shower head 230, but a configuration of the wing 215 is not limited thereto. For example, the wing 215 may be fixed to the sidewalls 213 and 214 of the chamber 210.

A supply port 216, which is connected to the gas supply 240 and supplies a processing gas into the chamber 210, is provided in the sidewall 213 of the chamber 210. An exhaust port 217, which is connected to the exhaust system 250 and exhausts the interior of the chamber 210, is provided in the sidewall 214 of the chamber 210.

The supply port 216 may be provided between the stage 220 and an end portion of the wing 215. Thus, when the substrate 10 (W) is raised and supported in a vicinity of the wing 215, a gas flows toward the back surface 12 of the substrate 10 (W), so that the inhibition component 20 is formed on the back surface 12 of the substrate 10 (W).

The gas supply 240 constitutes a supply nozzle provided at the supply port 216 of the chamber 210 and supplies the processing gas into the chamber 210. The gas supply 240 may include a gas source 241, a flow rate controller 242, and an opening/closing valve 243.

In the present embodiment, the gas supply 240 is configured to supply the processing gas from the gas source 241 to the supply port 216 via the flow rate controller 242. The flow rate controller 242 may include, for example, a mass flow controller (MFC) or a pressure-controlled flow rate controller. The gas supply 240 may include a flow modulation device that modulates or pulses a flow rate of the processing gas.

In the present disclosure, a gas containing the above-mentioned inhibition component 20 (1-octadecanethiol) (hereinafter referred to as an inhibition gas) is used for the processing gas supplied from the gas source 241 into the chamber 210 by the gas supply 240. In the gas supply 240, the gas containing the inhibition component 20 (1-octadecanethiol) (the inhibition gas) is supplied from the gas source 241.

When the processing gas (the inhibition gas) is supplied into the chamber 210, an inert gas (such as argon) may be mixed with the processing gas and supplied into the chamber 210 as a carrier gas for the processing gas. In addition, when the supply of the inhibition gas is stopped, the inert gas (such as argon) may be supplied into the chamber 210 as a purge gas for purging the substrate 10 (W).

The exhaust system 250 is connected to an exhaust nozzle 251 provided at the exhaust port 217 of the chamber 210. The exhaust system 250 may include a pressure regulating valve and a vacuum pump. The vacuum pump may include a turbo molecular pump, a roughing vacuum pump, or a combination thereof.

The controller 260 controls processing of the substrate. The controller 260 performs controlling operations of respective components of the substrate processing apparatus 200. For example, the controller 260 performs controlling a supply and stop of the processing gas (the purge gas or the inhibition gas) by opening and closing the opening/closing the valve 243, controlling the gas flow rate by the flow rate controller 242, controlling the exhaust by the exhaust system 250, and controlling the temperature of the substrate W or the temperature of the processing gas by the heater 224.

The controller 260 may be, for example, a computer or the like. In addition, a computer program for operating respective components of the substrate processing apparatus 200 is stored in a storage medium. The storage medium may be, for example, a flexible disk, a compact disc, a hard disk, a flash memory, a DVD, or the like.

In the present disclosure, the entire controller 260 is configured as a part of the substrate processing apparatus 200, but controller 260 is not limited to this configuration. A part of the controller 260 may be configured as a part of the substrate processing apparatus 200. Alternatively, a part or the entirety of the controller 260 may be provided separately from the substrate processing apparatus 200. In addition, the controller 260 may also serve as the controller 160 of the above-described substrate processing apparatus 100.

In the present disclosure, in the substrate processing apparatus 200, the processing of the substrate is controlled by the controller 260, and step S11 described above is executed to supply the inhibition component 20 to the back surface 12 of the substrate 10 (W) (see FIGS. 1, 3, 12, and 16).

Specifically, when a transfer mechanism (not shown) that supports the substrate 10 (W) is loaded into the chamber 210 under the control of the controller 260, the substrate 10 (W) is raised by the lift pins 222 to approach the wing 215. In addition, the gas containing the inhibition component 20 (1-octadecanethiol) (the inhibition gas) is supplied from the gas source 241 to a chamber lower portion 210B in the chamber 210, so that the inhibition component 20 is adsorbed only on the back surface 12 of the substrate 10 (W) (see FIG. 1, step S11, and FIGS. 2, 3, 12, and 16).

In the present embodiment, in the substrate processing apparatus 200, the substrate 10 having the inhibition component 20 formed on the back surface 12 is unloaded from the chamber 210 of the substrate processing apparatus 200 and is loaded into the process container 101 of the substrate processing apparatus 100. Thereafter, in the substrate processing apparatus 100, the gas supply 120 is controlled so that a gas (catalyst gas) containing the catalyst component 30 (TMA) is supplied from the gas source 121a into the process container 101 to adsorb the catalyst component 30 on the front surface 11 of the substrate 10 (W) on which the inhibition component 20 has not been adsorbed (see FIG. 1, step S12, and FIGS. 3, 4, 8, 9, and 15).

In addition, in the present embodiment, the gas supply 120 is controlled so that a gas (film-forming gas) containing the film-forming component 40 (TPSOL) is supplied from the gas source 122a into the chamber 210 to form the insulating film 50 (silicon oxide film) on the front surface 11 of the substrate 10 (W) on which the catalyst component 30 has been adsorbed (see FIG. 1, step S13, and FIGS. 5, 6, 10, 11, and 15).

In addition, in the present embodiment, plasma of an oxygen-containing gas is supplied into the process container 101 to remove the inhibition component 20 adsorbed on the substrate 10 (W). Specifically, after forming the insulating film 50 (silicon oxide film) on the front surface 11 of the substrate 10 (W), plasma of the oxygen-containing gas is supplied from the gas source 123a into the process container 101, and RF power is applied by the radio-frequency power supply 135 to generate the plasma of the oxygen-containing gas in the process container 101.

As a result, the inhibition component 20, which is adsorbed on the back surface 12 of the substrate 10 (W) after the insulating film 50 is formed on the front surface 11 of the substrate 10 (W), is removed from the substrate 10 (W) (see FIG. 1, step S16, and FIGS. 6, 7, and 15).

With the substrate processing apparatus of the present embodiment, substantially the same effects as those of the above-described substrate processing method can be obtained. That is, in the substrate processing apparatus of the present embodiment, by supplying the inhibition component 20 to the front surface 11 or the back surface 12 of the substrate 10 (W) before the catalyst component 30 is supplied into the chamber 210, adsorption of the catalyst component 30 on the substrate 10 (W) is inhibited, whereby the catalyst component 30 is not adsorbed on the front surface 11 or the back surface 12 of the substrate 10 (W) to which the inhibition component 20 has been supplied (see FIGS. 1, 4, and 15).

As a result, even when the film-forming component 40 is supplied to the substrate 10 (W) on which the catalyst component 30 is not adsorbed, an insulating film such as a silicon oxide film is not formed on the substrate 10 (W) (see FIGS. 5 and 6). Therefore, according to the present embodiment, it is possible to form a film selectively on different surfaces of the substrate 10 (W).

In addition, in the present embodiment, by supplying the inhibition component 20 only to the back surface 12 of the substrate 10 (W), the catalyst component 30 is adsorbed on the front surface 11 of the substrate 10 (W) while being not adsorbed on the back surface 12 of the substrate 10 (W). In such a state, when the film-forming component 40 is supplied to the substrate 10 (W), the insulating film 50 is formed on the front surface 11 of the substrate 10 (W) and is not formed on the back surface 12 of the substrate 10 (W). Therefore, in the present embodiment, the insulating film 50 can be formed selectively on the front surface 11 of the substrate 10 (W).

In the present embodiment, by removing the inhibition component 20 adsorbed on the substrate 10 (W), the inhibition component 20 adsorbed on the substrate 10 (W) can be removed from the substrate 10 (W). In addition, by removing the inhibition component 20 adsorbed on the substrate 10 (W) after forming the insulating film 50 (silicon oxide film) on the front surface 11 of the substrate 10 (W), the inhibition component 20, which has become unnecessary after the insulating film 50 is formed on the substrate 10 (W), can be removed from the substrate 10 (W).

In addition, in the present embodiment, by supplying plasma of the oxygen-containing gas to the substrate 10 (W) when removing the inhibition component 20 adsorbed on the substrate 10 (W), even when the adsorption force of the inhibition component 20 to the substrate 10 (W) is strong, the unnecessary inhibition component 20 can be removed from the substrate 10 (W). In addition, even when a film of the inhibition component 20 adsorbed on the substrate 10 (W) is thick, the unnecessary inhibition component 20 can be removed from the substrate 10 (W).

Although the embodiments of the present disclosure have been described above, the present disclosure is not limited to these embodiments, and various modifications and changes can be made within the scope of the disclosure described in the claims.

This application is based upon and claims the benefit of priority from Japanese Patent Application No. 2020-186153, filed on Nov. 6, 2020, the entire contents of which are incorporated herein by reference.

### EXPLANATION OF REFERENCE NUMERALS

10: substrate, 11: front surface, 12: back surface, 20: inhibition component, 30: catalyst component, 40: film-forming component, 50: insulating film, 100: substrate processing apparatus, 101: process container, 102: ceiling plate, 103: manifold, 104: seal, 105: wafer boat, 106: rod, 107: heat insulating tube, 108: table, 109: lid, 110: rotary shaft, 111: magnetic fluid seal, 112: seal, 113: arm, 120: gas supply, 121, 123, 124: gas supply pipe, 121a, 122a, 123a: gas source, 121b, 122b, 123b: flow rate controller, 121c, 122c, 123c: opening/closing valve, 121g, 123g: gas hole, 130: plasma generation mechanism, 131: opening, 132: plasma partition wall, 133: plasma electrode, 134: power supply line, 135: radio-frequency power supply, 136: insulation protection cover, 140: exhaust port, 141: exhaust port cover, 142: exhaust pipe, 143: pressure control valve, 144: exhaust device, 150: heating mechanism, 160: controller, 200: substrate processing apparatus, 210: chamber, 210A: space, 211: ceiling surface, 212: bottom surface, 213, 214: sidewall, 215: wing, 216: supply port, 217: exhaust port, 220: stage, 221: mounting table, 222: lift pin, 230: shower head, 231: gas supply, 232: gas diffusion chamber, 233: gas discharge port, 240: gas supply, 241: gas source, 242: flow rate controller, 243: opening/closing valve, 250: exhaust system, 251: exhaust nozzle, 260: controller

1-13. (canceled)

14. A substrate processing method comprising:
a catalyst component supplying process of supplying a catalyst component, which is to be adsorbed on a substrate, to the substrate;
a film-forming component supplying process of supplying a film-forming component, which forms an insulating film on the substrate in the presence of the catalyst component, to the substrate; and
an inhibition component supplying process of supplying an inhibition component, which is to be adsorbed on the substrate and inhibits adsorption of the catalyst component on the substrate, to a front surface or a back surface of the substrate,
wherein the inhibition component supplying process is performed before the catalyst component supplying process.

15. The substrate processing method of claim 14, wherein in the inhibition component supplying process, the inhibition component is supplied only to the back surface of the substrate.

16. The substrate processing method of claim 15, wherein the film-forming component is an organic silane compound.

17. The substrate processing method of claim 16, wherein the organic silane compound is tris(tert-pentoxy)silanol or tris(tert-butoxy)silanol.

18. The substrate processing method of claim 17, wherein the catalyst component is a metal compound.

19. The substrate processing method of claim 18, wherein the metal compound is trimethylaluminum or trimethylgallium.

20. The substrate processing method of claim 19, wherein the catalyst component supplying process and the film-forming component supplying process are repeated.

21. The substrate processing method of claim 20, wherein the inhibition component is an organic sulfur compound or an organic silane compound, which forms a self-assembled monolayer on the substrate.

22. The substrate processing method of claim 21, wherein the inhibition component supplying process, the catalyst component supplying process, and the film-forming component supplying process are repeated.

23. The substrate processing method of claim 22, further comprising a removing process of removing the inhibition component adsorbed on the substrate,
wherein the removing process is performed after the film-forming component supplying process.

24. The substrate processing method of claim 23, wherein in the removing process, plasma of an oxygen-containing gas is supplied to the substrate.

25. The substrate processing method of claim 23, wherein in the removing process, H2, NH3, plasmarized H2 or NH3, or a hydrazine-containing gas is supplied to the substrate.

26. The substrate processing method of claim 14, wherein the film-forming component is an organic silane compound.

27. The substrate processing method of claim 26, wherein the organic silane compound is tris(tert-pentoxy)silanol or tris(tert-butoxy)silanol.

28. The substrate processing method of claim 14, wherein the catalyst component is a metal compound.

29. The substrate processing method of claim 28, wherein the metal compound is trimethylaluminum or trimethylgallium.

30. The substrate processing method of claim 14, wherein the catalyst component supplying process and the film-forming component supplying process are repeated.

31. The substrate processing method of claim 14, wherein the inhibition component is an organic sulfur compound or an organic silane compound, which forms a self-assembled monolayer on the substrate.

32. The substrate processing method of claim 14, wherein the inhibition component supplying process, the catalyst component supplying process, and the film-forming component supplying process are repeated.

33. A substrate processing apparatus comprising a controller that controls processing of a substrate,
wherein the controller performs a control to:
supply a catalyst component, which is to be adsorbed on the substrate, to the substrate;
supply a film-forming component, which forms an insulating film on the substrate in the presence of the catalyst component, to the substrate;
supply an inhibition component, which is to be adsorbed on the substrate and inhibits adsorption of the catalyst component on the substrate, to the substrate; and
supply the inhibition component to a front surface or a back surface of the substrate before the catalyst component is supplied to the substrate.
